(19) United States
(12) Patent Application Publication
(10) Pub. No.: US 2022/0083715 A1
(43) Pub. Date: Mar. 17, 2022

(54) MACHINE LEARNED HIGH-ACCURACY SATELLITE DRAG MODEL (HASDM) WITH UNCERTAINTY QUALIFICATION (HASDM-ML-UQ)

(71) Applicant: West Virginia University Board of Governors on Behalf of West Virginia University, Morgantown, WV (US)

(72) Inventor: Piyush M. Mehta, Morgantown, WV (US)

(21) Appl. No.: 17/473,497

(22) Filed: Sep. 13, 2021

Related U.S. Application Data
(60) Provisional application No. 63/078,361, filed on Sep. 15, 2020.

(51) Int. Cl. G06F 30/27

(52) U.S. Cl. CPC G06F 30/27

(57) ABSTRACT

The present disclosure relates to an upper-atmospheric mass density prediction model with robust and reliable uncertainty estimates in accordance with various embodiments of the present disclosure. The upper-atmospheric mass density model is developed based on the SET HASDM density database. In various embodiments, PCA is used to reduce the spatial dimension of the dataset. The input sets used to train the mass density model contains a time series for the geomagnetic indices. The mass density prediction model is trained to output a mass density map for accurately prediction trajectories of satellites. For example, a likelihood of collision associated with a given object can be determined based at least in part on the mass density map. Analysis of the mass density map along with the likelihood of collision can used to determine a trajectory for the given object in space.

### CROSS REFERENCE TO RELATED APPLICATION

This application claims benefit of U.S. Provisional Application No. 63/078,361 filed Sep. 15, 2020, entitled MACHINE LEARNING FOR RAPID EXPLOITATION OF THE LARGE HIGH-ACCURACY SATELLITE DRAG MODEL (HASDM DATASET), which is hereby incorporated by reference in its entirety for all purposes.

### STATEMENT REGARDING FEDERALLY SPONSORED RESEARCH OR DEVELOPMENT

This invention was made with government support under grant number #80NSSC20C0292 awarded by the NASA Established Program to Stimulate Competitive Research. The Government has certain rights in the invention.

### BACKGROUND

Debris in Low Earth Orbit (LEO) endangers the International Space Station (ISS), the Hubble Space Telescope and the future commercialization of space. Below an altitude of approximately 2,000 kilometers, drag impacts spacecraft significantly. Although air density is much lower than at sea level, air resistance at those altitudes produce sufficient drag to pull satellites traveling in LEO towards the Earth. When the Sun is active, the extra energy increases drag on satellites. When satellites drop down to a higher density layer of the atmosphere, they experience a stronger drag force. To compensate, satellites in LEO boost their orbits multiple times per year. During peak solar activity years, satellites maneuver themselves every 2-3 weeks to maintain their orbit. Solar wind during a geomagnetic storm on Earth exacerbates drag on satellites by producing spikes in upper atmosphere temperature and density. When these orbital changes occur in the wake of a solar storm, the North American Aerospace Defense Command (NORAD) tracks and re-identifies hundreds of objects and their new orbits. During the March 1989 solar storm, NASA's Solar Maximum Mission (SMM) spacecraft experienced a severe spike in atmospheric drag. As a result, its readings orbital dropped “as if it hit a brick wall.”

NASA and the US Air Force Space Command track objects flying in space for potential collisions. In February 2009, collision avoidance became a top priority after two intact spacecraft accidentally crashed at an altitude of 790 km. Their debris has since separated into different orbital planes and threatened other satellites. Currently, the US Space Surveillance Network (SSN) tracks over 20,000 man-made objects larger than 10 cm in size, which are known as the “cataloged” population. However, not all objects can be tracked and cataloged. Either way, orbit prediction for avoiding collisions that can lead to damage to systems (e.g. puncture unprotected fuel lines, erode thermal surfaces, and damage optics) affecting mission performance or catastrophic damage to the satellite as a whole rendering it nonoperational remains a major challenge. Although the International Space Station uses meteor bumpers to mitigate the impact of space debris, the only way to avoid collision damage altogether is to maneuver out of the way. These maneuvers are expensive and impact sensitive experiments on board. Currently, the SSN's orbit forecasting system only gives satellites three days warning.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates and example of the space density prediction system of the present disclosure comprising the HASDM-ML as compared to the current HASDM system in accordance to various embodiments

FIGS. 2A-2C are example plots showing graphical representations associated with the uncertainty in the predictions according to various embodiments of the present disclosure.

FIG. 3 illustrates an example of PCA with regard to a first principal component and a second principal component according to various embodiments of the present disclosure.

FIG. 4 provides an example diagram that illustrates the reduction of the images as well as the reconstruction of the images using the predicted coefficients according to various embodiments of the present disclosure.

FIG. 5 provides an example diagram of the use of the dense model according to various embodiments.

FIG. 6 provides an example diagram of the combined model according to various embodiments.

FIG. 7 illustrates a graphical representation of F₁₀ and aₚ at available data points shaded to show the training, validation, and test spits, according to various embodiments.

FIG. 8 is an example graphical representation illustrating the first ten PCA coefficients (a₁) generated for the HASDM database along with F₁₀ and aₚ, in accordance with various embodiments of the present disclosure.

FIG. 9 is a graphical representation illustrating the expected vs. observed confidence of all 10 PCA coefficients for HASML-ML on the test set in accordance to various embodiments of the present disclosure.

FIGS. 10A-10D are graphical representations illustrating testing results associated with the CHAMP orbit. In particular, FIG. 10A shows the HASDM and mean HASDM-ML density interpolated to CHAMP positions, FIG. 10B shows the expected vs observed calibration curve, FIG. 10C shows F₁₀ and aₚ for the period corresponding to FIG. 10A, and FIG. 10D shows the difference between expected and observed confidence corresponding to FIG. 10B. Discontinuities in FIG. 10A and FIG. 10C represent data gaps.

FIGS. 11A-11D are graphical representations illustrating testing results associated with the GRACE-A orbit.

FIG. 12 includes graphical representations illustrating HASDM and HASDM-ML orbit-averaged densities during four geomagnetic storms with confidence bounds and the associated calibration curves.

FIG. 13 is an example flowchart that includes portions of functionality of a space density prediction system executed in a computing environment according to various embodiments of the present disclosure.

FIG. 14 is a schematic block diagram that provides one example illustration of a computing environment according to various embodiments of the present disclosure.

### DETAILED DESCRIPTION

The present disclosure relates to a space density prediction system that incorporates machine learning to train and update models that output density maps that can be used for space traffic management according to various embodiments of the present disclosure. Space traffic management is difficult. Monitoring and predicting the accurate, real-time position of satellites for collision avoidance in low earth orbit is an engineering challenge. The dominant source of error in satellite prediction tracking models in low Earth orbit is in the determination of atmospheric drag. The High Accuracy Satellite Drag Model (HASDM) was developed by the U.S. Air Force Space Command (AFSPC) between 2000-2005 to help solve this problem. It is a data assimilative modeling system using the Jacchia-Bowman 2008 (JB2008) thermospheric density model plus continuously derived densities from several dozens of calibration satellites to achieve <5% density uncertainty at most epochs. Under authority from the AFSPC, Space Environment Technologies (SET) has extracted two solar cycles of operational HASDM data for scientific use and this is called the SET HASDM database. In particular, the SET HASDM database comprises the input data (e.g., solar and geomagnetic drivers) and the output data (e.g., 3D density maps) associated with the HASDM model during the two solar cycles. Navigating and extracting information from this database quickly and efficiently to manage satellite space traffic is currently complex and tedious. Also, the database does not afford predictive capabilities. The HASDM model, considered the state-of-the-art and used operationally by the Joint Space Operations Center (JSPoC), is not available to the public or commercial sector. The SET HASDM database is the first time the data will be made available to the public.

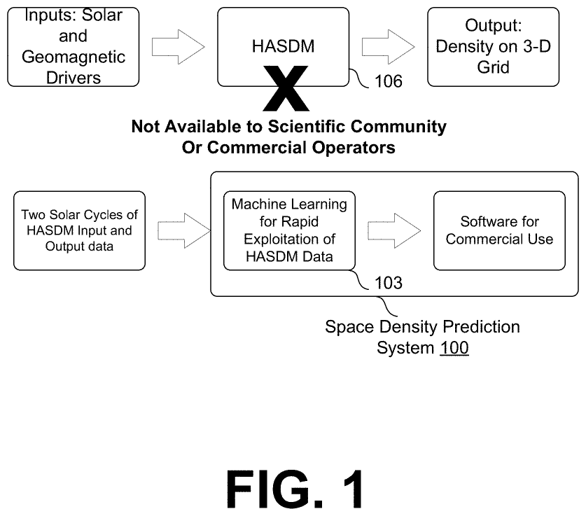

Disclosed herein are various embodiments related to a space density prediction system with uncertainty qualification (hereinafter referred to as “HASDM-ML-UQ”) that uses machine learning (ML) algorithms to characterize, for rapid access, the multiple gigabyte-sized two-solar cycle SET HASDM database by using JB2008 empirical thermospheric density model indices and other physical drivers (e.g., F₁₀, Dst). The HASDM-ML densities can be used with Two-Line Elements (TLEs) of non-assimilated objects to create more accurate ballistic coefficients, B*, for catalogued objects that when combined with HASDM-ML model can significantly improve predictive space operations for collision avoidance and Space Traffic Management. The various embodiments of the present disclosure make it possible for the commercial sector to use the HASDM database. FIG. 1 illustrates and example of the space density prediction system 100 of the present disclosure comprising the HASDM-ML 103 as compared to the current HASDM system 106 in accordance to various embodiments.

The SSN relies on on-orbit propagation models for collision avoidance. These same models are also useful for satellite re-entry predictions and long-term debris forecasts. For propagation models to be accurate and efficient, they rely on assumptions about the two primary forces that act on a space object in LEO—atmospheric drag and the gravitational pull of the Earth. Satellite drag involves the most variability and orbits modeling errors. Propagation models have to account for drag despite the solar wind and the potential impact of lower atmosphere waves from below. Therefore, most orbit determination applications use empirical atmospheric neutral density models. These models rely on historical observations of which parametric equations have been fitted. Empirical models estimate drag while accounting for variations in the upper atmosphere: local time, latitude, season, solar weather, and geomagnetic activity. The most commonly used ones include the Jacchia, High Accuracy Satellite Drag Model (HASDM), Mass Spectrometer Incoherent Scatter (MSIS), Jacchia-Bowman (JB), Drag Temperature Mod& (DTM), and Global Average Mass Density Mod& (GAMDM).

Physics-based models also calculate atmospheric drag information. Unlike empirical models, physics models seek to calculate a physical quantity with the laws of physics. By assessing upper atmosphere winds, composition and densities, physics models can provide a realistic representation of neutral density. On the other hand, their accuracy depends on the magnitude, distribution, and timing of solar weather and magnetic storm events.

NASA increasingly provides start-up companies access to space. Currently, 2,200 satellites orbit the Earth. Telecommunications companies launch dozens of satellites each month with the goal of accelerating high-speed, global broadband internet access. OneWeb in the UK, for example, is on track to launch 650 satellites in orbit by 2021. Elon Musk's SpaceX® will launch nearly 1250 communication satellites in LEO by the end of 2020. SpaceX® plans to launch 42,000 satellites for its Starlink Internet system. Amazon® recently announced Project Kuiper, a plan to launch a 3000-satellite “mega-constellations” for enterprise users.

For SSN, NASA, NORAD, and other government agencies to successfully police these commercial ventures, these companies need to ensure that their satellite systems won't hinder Earth's telescopes, disrupt deep-space radio frequencies, or collide with lethal or risk population debris. Two other groups specifically monitor space for collisions, the Space Data Association (an industry lobbying group), and the US Air Force's Joint Space Operations Center (JSpOC), a real-time provider of space situational awareness information. Unlike SSN, JSpOC executes the operational command and control of space forces to the military's global objectives. If satellites pollute LEO without proper management, floating debris could cause “a Kessler syndrome”—a catastrophic chain of collisions that hinders space travel. Although the possibility of a Kessler Syndrome is remote, it would threaten the US Air Force's military dominance in space. Therefore, the US government treats floating space debris as a national security threat.

Amazon's® proposed mega-constellations will likely expand broadband access to billions of people. At the same time, their proximity to nearby satellite constellations will require SSN and/or JSpOC to issue collision-avoidance maneuver instructions more frequently—up to eight times per hour. To adequately prepare, the Federal Communications Commission (FCC) requires operators to disclose collision risk, satellite maneuver protocols, and decommissioning plans before launch. These disclosures reduce both operational risks and computational cost to government agencies. Nevertheless, operators disagree about the minimum necessary distance satellites should maintain from each other. To avoid collisions, OneWeb wants other operators to stay at least 125 kilometers away from its constellations. Amazon, on the other hand, argued in FCC filings that a 40-kilometer gap is sufficient. As LEO industry grows, operators will need greater data and expertise about how atmospheric drag and solar weather impacts their empirical and physics-based models.

In view of the foregoing, it will be beneficial to provide a space density prediction system that includes machine learning based models that can output full density grids (e.g., longitude, latitude, and altitude) that can be used for commercial use. In some embodiments, the space density prediction system can further determine a likelihood of collision with respect to a given satellite or associated object based at least in part on an analysis of the outputted density grids. By having the knowledge of the likelihood of collision, an entity can monitor their satellites and move a given satellite when necessary to avoid collisions.

The system of the present disclosure comprises atmospheric drag machine learning models. The system of the present disclosure takes advantage of gigabytes of data captured by the SET corporation and the US Air Force Space Command (AFSPC)'s High Accuracy Satellite Drag Model (HASDM). The system of the present disclosure incorporates machine learning to generate models that are configured to predict atmospheric drag for commercial use. In some embodiments, the present disclosure incorporates proper orthogonal decomposition for dimensionality reduction with Bayesian Deep Learning for modeling in the reduced state with uncertainty quantification. However, it should be noted that the present disclosure is not limited aforementioned techniques and other machine learning techniques may be used as can be appreciated. According to various embodiments, the system of the present disclosure is operationally accurate and opens the door to commercial use of the SET HASDM database.

The present disclosure relates to a space density prediction system that can be used for LEO satellite traffic management. The system of the present disclosure is trained on multiple gigabytes of data (e.g., two solar cycles) captured by the Space Environment Technologies (SET) corporation from the US Air Force Space Command (AFSPC) JSpOC's High Accuracy Satellite Drag Model (HASDM) for scientific research covering the period from 2001-2020 (presently; continuously growing). HASDM is used operationally by JSpOC to make predictions of three-day maneuvers. Every three hours, HASDM uses a thermospheric density model and continuously derives densities from several dozen calibration satellites to achieve <5% density uncertainty. HASDM describes density as a function of latitude, local solar time, and altitude. A time-series filter then predicts the density correction parameters as a function of predicted solar radio flux index F_{10.7} and predicted geomagnetic storm index up to three days into the future. The estimated and predicted density fields are then used to first differentially correct all the drag influenced orbits (over 6000) in the NORAD catalog. Then, they are used to predict all satellite trajectories three days out.

Extracting information from the raw high-dimensional HASDM database is slow, complex, and tedious. Although the public may have access to some HASDM data, they do not have access to military-grade hardware, classified expertise, or software. Therefore, the embodiments of the present disclosure relate to a machine learning-based system configured to rapidly characterize the two-solar cycle SET HASDM database by using J82008 empirical thermospheric density model indices and other physical drivers (e.g. solar wind measurements at the LI point using satellites like ACE and/or DSCVOR).

In particular, an accessible and practical engineering solution to simulating large-scale, high-dimensional systems has been to develop a reduced order model (ROM) that represents the original system using a small number of parameters. While the original HASDM database may have been generated using only a small number of parameters from the JB2008 empirical thermospheric density model, generating a new density representation from high-dimensional model output is challenging. According to various embodiments, machine learning (ML) is used to develop a ROM to facilitate easy exploitation and rapid access of the information content of the HASDM database (HASDM-ML).

The main idea behind a ROM is to capture maximum variance with a small number of model parameters by separating temporal and spatial variations. Therefore, the two major components of the methodology are i) dimensionality reduction and ii) model identification through the correlation of inputs with the reduced dimensional state.

According to various embodiments of the present disclosure, Principal Component Analysis (PCA) for dimensionality reduction and artificial neural networks for modeling the reduced state with input drivers is applied. PCA decomposes the spatial variations into mutually orthogonal, time-independent coherent structures or basis functions (BFs; also known as principal components—PCs or empirical orthogonal functions—EOFs) that capture the covariance in space. This has the effect of reducing the spatial dimensions or degrees of freedom. The BFs are likely to represent physical dynamical processes, however, it may not always be the case. The time-dependent coefficients represent the weighting for the BFs and capture the temporal variations as a function of the input drivers. The BFs, and hence the ROM, is valid for the conditions represented in the training ensemble. The SET HASDM database covers close to two (2) full solar cycles and therefore the HASDM-ML model is universal and includes quantifiable uncertainties. According to various embodiments, nonlinear dimensionality reduction methods (e.g., convolutional autoencoders) may be used to improve the performance of the linear PCA method if needed.

The next step is to model and predict the variation of the coefficients (principal scores or reduced order state) as a function of the inputs/drivers. In some embodiments, Gaussian process regression (GPR) may be used because of its accuracy and robustness as a supervised machine learning technique. It is a nonparametric approach (e.g., does not take a functional form such as a polynomial) that calculates the probability distribution over all admissible functions that fit the data rather than calculating the probability distribution of parameters of a specific function. The output is assumed to have a multivariate Gaussian distribution, where the characteristics of the Gaussian model is dictated by the functional form of the covariance matrix or kernel. The training phase optimizes the free parameters of the covariance kernel such that the multivariate Gaussian best describes the distribution of the observed data points. GPR characterizes the response of a system or variable to changes in input conditions and can be used to predict the variable at a new set of input conditions using the posterior conditional probability. The advantage of GPR is that it inherently and accurately characterizes the uncertainty associated with predictions.

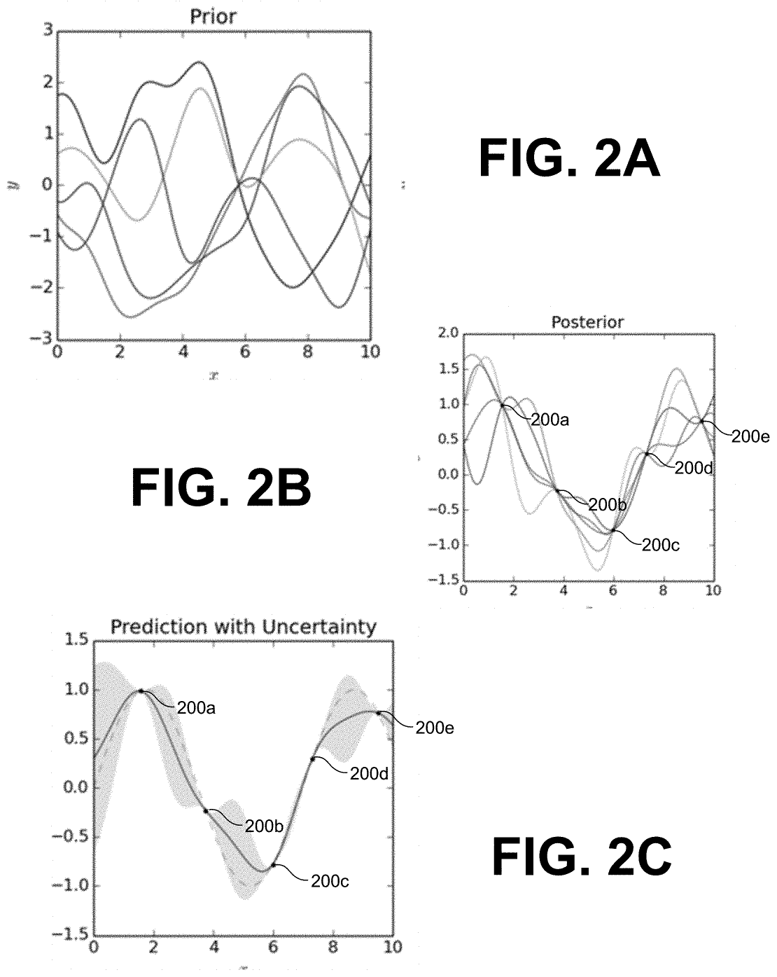

FIGS. 2A-2C illustrate example plots showing graphical representations associated with the uncertainty in the predictions. For example, FIG. 2A illustrates a plot showing five draws from a Gaussian process with a single input dimension. FIG. 2B illustrates a plot showing five draws from a Gaussian process condition on the observations 200 (e.g., 200a, 200b, 200c, 200d, 200e). FIG. 2C illustrates an example plot showing prediction conditioned on the observations 200 with uncertainty estimate.

Uncertainties are the smallest close to observed data points, larger when interpolating, and largest for extrapolation, which is intuitive. Therefore, model error is also determined. GPR has successfully been applied to satellite drag coefficient and neutral thermosphere mass density modeling.

In other embodiments, as discussed with regard to the Example, the models may leverage Monte Carlo (MC) dropout as an alternative to GPR to generate probabilistic outputs from which model uncertainty can be extracted. According to various embodiments, neural networks, i.e., a general ML algorithm known as a universal functional approximator, can also be employed to estimate the nonlinear mapping between input drivers and reduced density state.

Throughout the evolution of the HASDM Machine Learning (HASDM-ML) model of the space density prediction system of the present disclosure, there have been many different sets of inputs and outputs. Though there were many different input sets have been used over various versions of the model, there were only four output sets. These are: Principal Component Analysis (PCA) coefficients, Convolutional Autoencoder (CAE) coefficients, the full 24×19×27 density grid, and a reshaped 12312×1 density vector. For PCA or CAE coefficients, models are developed that can map from the full 24×19×27 grid to 10 or 20 coefficients. When a separate model is trained on these coefficients, PCA or CAE are used to map those predictions back to the density grid.

Table 1 includes examples of initial versions of inputs that were determined to be able to be applied to different HASDM-ML models relative to various versions of the model according to various embodiments of the present disclosure. In particular, Table 1 includes an example of different versions of models that can be incorporated in the system of the present disclosure. As will be discussed in greater detail with regard to Table 3, additional input sets have been used with additional versions of the model.

TABLE I
Initial Model Inputs and Outputs

| | Inputs | Outputs |
|---|---|---|
| v1 | F_{10.7}, F54b, ap, UT, doy | PCA Coefficients |
| v2 | F_{10.7}, F54b, ap, UT, doy | CAE Coefficients |
| v3 | F_{10.7}, F54b, ap, UT, doy | Full Density Grid |
| v4 | F_{10.7}, F54b, ap, Dst, UT, doy | CAE Coefficients |
| v5 | F_{10.7}, F54b, S_{10.7}, S54b, ap, Dst, UT, doy | CAE Coefficients |
| v6 | F_{10.7}, F54b, S_{10.7}, S54b, M_{10.7}, M54b, ap, | CAE Coefficients |
| | Dst, UT, doy | |
| v7 | F_{10.7}, F54b, S_{10.7}, S54b, M_{10.7}, M54b, Y_{10.7}, | CAE Coefficients |
| | Y54b, ap, Dst, UT, doy | |
| v8 | F_{10.7}, F54b, S_{10.7}, S54b, M_{10.7}, M54b, Y_{10.7}, | Full Density Grid |
| | Y54b, ap, Dst, UT, doy | |
| v9 | F_{10.7}, F54b, S_{10.7}, S54b, M_{10.7}, M54b, Y_{10.7}, | Density Vector |
| | Y54b, ap, Dst, UT, doy | |
| v10 | F_{10.7}, F54b, S_{10.7}, S54b, M_{10.7}, M54b, Y_{10.7}, | Full Density Grid |
| | Y54b, ap, Ap, Dst, UT, doy | |
| v11 | F_{10.7}, F54b, S_{10.7}, S54b, M_{10.7}, M54b, Y_{10.7}, | Density Vector |
| | Y54b, ap, Ap, Dst, UT, doy | |

In various embodiments, the model inputs described in Table 1 may include solar indices/proxies (S₁₀, M₁₀, Y₁₀, F₁₀), geomagnetic indices (Ap, ap and Dst), day of the year (doy), latitude, longitude, and time of day (UT), and/or other inputs as can be appreciated. In Table 1, the solar indices/proxies inputs of F54b, S54b, M54b, Y54b correspond to 54 day averaged values. In addition, the value for ap is a daily value while the value of Ap is a value associated with a three hour range. These inputs can be extracted from the SET database and/or separately collected/calculated as can be appreciated. According to various embodiments, the input drivers can also include solar wind parameters (e.g. velocity, temperature) that can be obtained from NASA's Omniweb services.

The primary output is mass density on the three-dimensional grid (e.g., latitude, longitude, altitude). However, in some embodiments, the output number density and temperature may be included on the 3-D grid. According to various embodiments, the mass density output can be analyzed for space traffic management. For example, in various embodiments, the space density prediction system can analyze the density output for a given satellite based at least in part on satellite data (size, location, material, etc.) and/or other atmospheric characteristics associated with the given satellite to determine a likelihood of collision for the given satellite with another object. Based on the likelihood of collision, the given satellite can be moved. For example, if the likelihood of collision is below a given threshold, the given satellite may remain in the same location. However, if the likelihood of collision meets or exceeds a given threshold, the given satellite may be moved to avoid the potential collision.

The following provides additional disclosure on the development of the models of the space density prediction system according to various embodiments. It should be noted that the space density prediction system is not limited to the machine learning techniques as described below and can incorporate other machine learning techniques as can be appreciated.

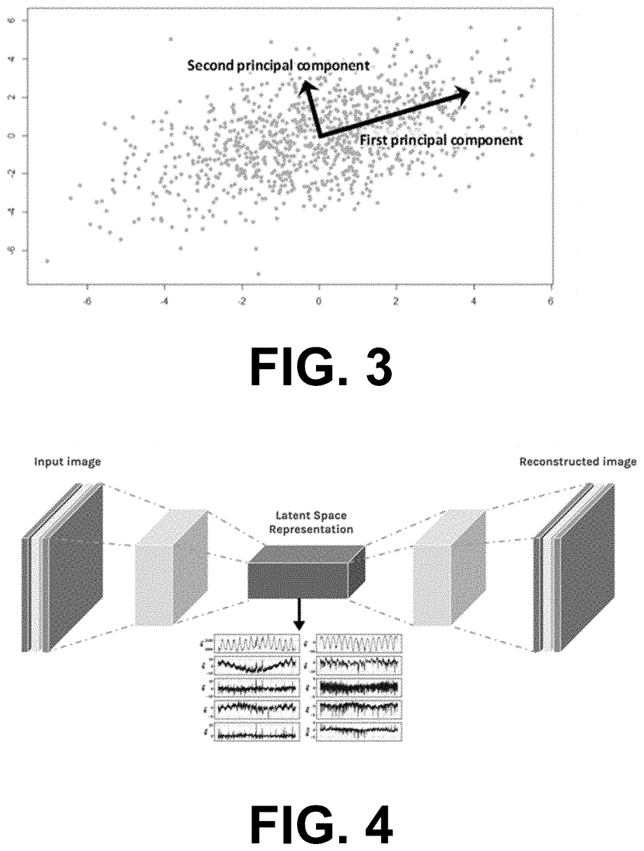

Principal Component Analysis: PCA is a model decomposition technique that separates data into the components that contribute from most to least of the variance in the system. In the context of HASDM-ML, it allows the density dataset (12,312 spatial density values every time step) to be reduced into twenty (20) coefficients every time step while retaining ˜97% of the information. Therefore, the model of the present disclosure can be trained to learn the coefficients based on the inputs and PCA can convert those predictions to the 24×19×27 grid with less than 3% error on average. FIG. 3 illustrates an example of PCA with regard to a first principal component and a second principal component. It helps identify the dominant dimensions of variation and therefore developed a reduced representation of the full 3-D density grid.

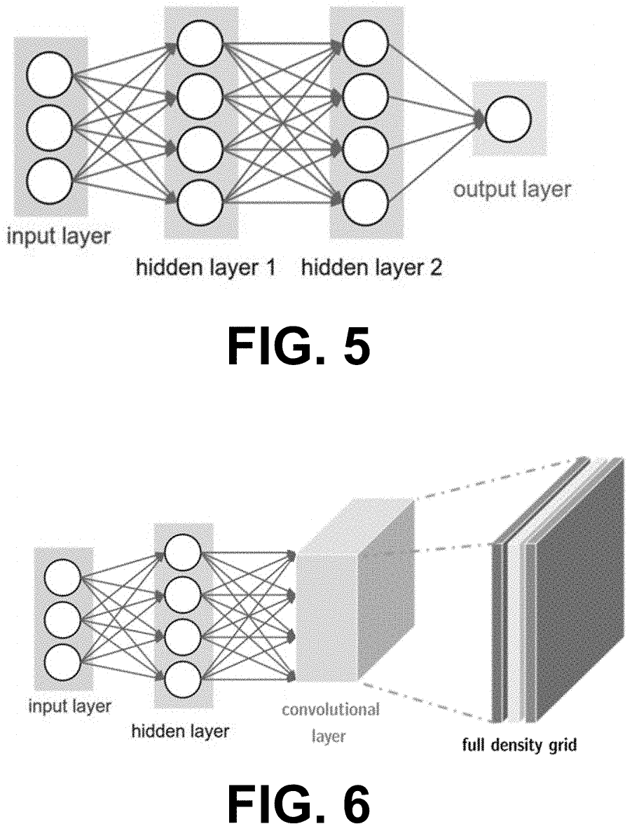

Convolutional Autoencoder. CAE is a type of neural network that is trained to take an image (e.g., a density grid) and reduce it down to a given size (e.g. 10×1), then expand it back to recreate the original image. When it is trained to the point that it can recreate the densities very well, a number of coefficients (e.g., 10) for every time step can be created and a separate model can be trained using the created coefficients n those. Then, the CAE can be used to transform the predicted coefficients back to the full size, also with little error. FIG. 4 provides an example diagram that illustrates the reduction of the images as well as the reconstruction of the images using the reduced state coefficients. The PCA and the CAE are both dimensionality reduction methods aimed to separate spatial and temporal variations. CAEs are non-trivial to train but can achieve nonlinear dimensionality reduction, unlike the PCA. In addition, a benefit to using CAEs, over other autoencoders, likes in the number of model parameters. Since they are not fully connected the result is quicker training and decreased likelihood of overfitting.

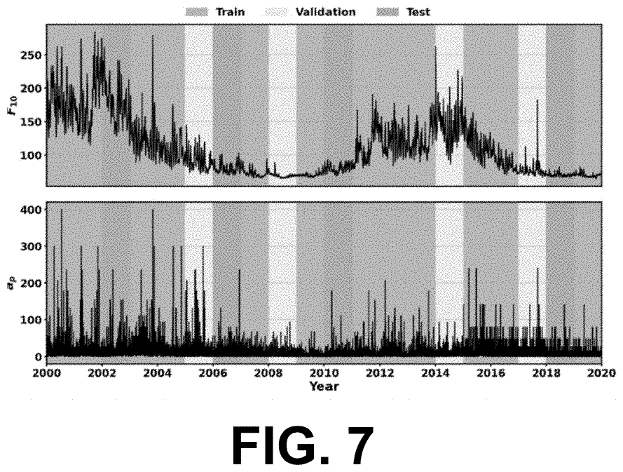

Dense Model: Dense (or Sequential) models are a type of regression model that learn input/output (I/O) relationships of a dataset. Unlike PCA or CAE, they can take a single vector as an input (inputs from table) and output either a set of coefficients or a flattened, or one-dimensional, density grid. This is what was used to learn the I/O relationships in the various dense model versions (e.g., v1, v2, v4, v5, v6, v7, v9, and v11 of Table 1). For example, in some dense model versions (e.g., v1, v2, v4, v5, v6, and v7), the dense models were trained on 10 or 20 coefficients. However, the 3D density grid was reshaped into a single 12312×1 vector and used dense models v9 and v11 of Table 1 to learn the I/O relationship. FIG. 5 provides an example diagram of the use of the dense model according to various embodiments.

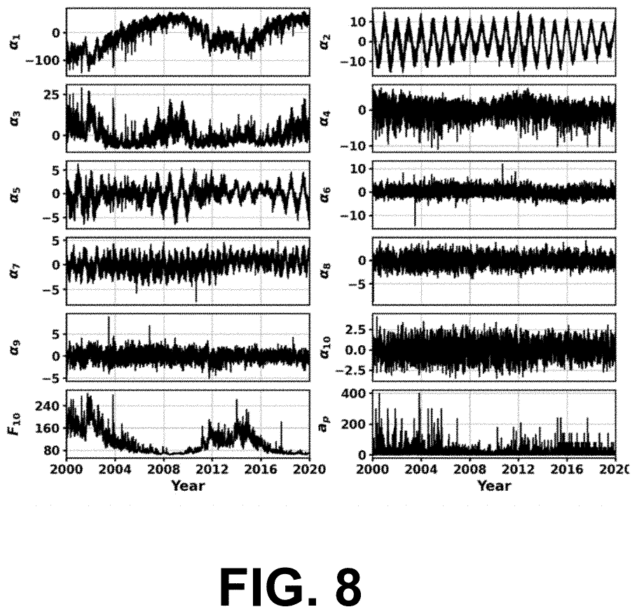

Combined Model: This combined model is part dense and part convolutional. Regular convolutional models cannot take a single vector as an input and output a 3D grid or image. Therefore, according to various embodiments the first half of a dense model can be combined with the latter half of a convolutional model to utilize both methods. This implementation was used for dense models v3, v8, and v10 from Table 1. FIG. 6 provides an example diagram of the combined model according to various embodiments.

### Example

The following example describes an upper-atmospheric mass density model with robust and reliable uncertainty estimates in accordance with various embodiments of the present disclosure. The upper-atmospheric mass density model is developed based on the SET HASDM density database. As discussed, this database, created by Space Environment Technologies (SET), contains twenty years of outputs from the U.S. Space Force's High Accuracy Satellite Drag Model (HASDM), which represents the state-of-the-art for density and drag modeling. In various embodiments, PCA is used to reduce the spatial dimension of the dataset, which makes uncertainty quantification feasible. Three loss functions (e.g., mean square error (MSE), negative logarithm of predictive density (NLPD), and continuous ranked probability score (CRPS)) are tested along with three input sets to identify the best-performing model. This is achieved by optimizing nine models (all three loss functions and input sets) and comparing the accuracy of the predictions and the reliability of its uncertainty estimates. The models leverage Monte Carlo (MC) dropout to generate probabilistic outputs from which model uncertainty can be extracted. Using an input set containing a time series for the geomagnetic indices resulted in the most accurate models. In addition, the model using this input set in addition to the NLPD loss function had sufficient performance (10% mean absolute error) and the most calibrated/reliable uncertainty estimates on independent data. As described, the best model's uncertainty capabilities in the density space were tested along two satellite orbits from 2002-2010. This showed the model was highly reliable across all space weather conditions.

Methodology—Data

As previously discussed, HASDM is an assimilative framework using the Jacchia-Bowman 2008 Empirical Thermospheric Density Model (JB2008) as a background density model in accordance to various embodiments. HASDM improves upon the known density correction work to modify thirteen (13) global temperature correction coefficients with its DCA algorithm. HASDM uses observations of more than seventy carefully chosen calibration satellites to estimate local density values. The satellite orbits span an altitude range of 190-900 km although a majority are between 300 and 600 km. The HASDM algorithm of the present disclosure uses a prediction filter for the correction coefficients that employs wavelet and Fourier analysis. Another highlight of HASDM's novel framework of the present disclosure is its segmented solution for ballistic coefficient (SSB). This allows the ballistic coefficient estimate to deviate over the fitting period for the satellite trajectory estimation.

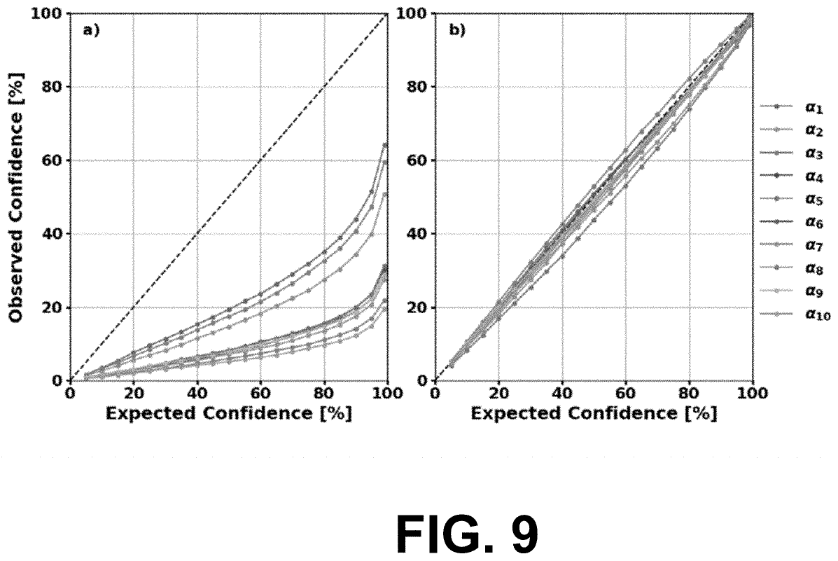

SET validates the HASDM output each week and archives the results. The archived values from 2000-2020 make up the SET HASDM density database, upon which the present disclosure is based. The database contains density predictions with 15° longitude, 10° latitude, and 25 km altitude increments spanning from 175-825 km. This results in 12,312 grid points for every three hours between the start of 2000 to the end of 2019. According to various examples of the present disclosure, the data is split into training, validation, and test data using 60%, 20%, and 20%, respectively shown in FIG. 7. In particular, FIG. 7 illustrates a graphical representation of F₁₀ and aₚ at available data points shaded to show the training, validation, and test spits, according to various embodiments.

Table 2 shows the number of time steps in the SET HASDM density database across various space weather conditions. The cutoff values for F₁₀ and aₚ are obtained from Licata, R. J., W. K. Tobiska, and P. M. Mehta (2020b), Benchmarking Forecasting Models for Space Weather Drivers, Space Weather, 18(10), e2020SW002,496, doi:https://doi.org/10.1029/2020SW002496, where they were used to bin space weather driver forecasts.

TABLE 2
Number of Samples for Different Space Weather Conditions
Across the SET HASDM Density Database

| | | 75 < F₁₀ ≤ | 150 < F₁₀ ≤ | | |
|---|---|---|---|---|---|
| | F₁₀ ≤ 75 | 150 | 190 | F₁₀ > 190 | All F₁₀ |
| aₚ ≤ 10 | 13,839 | 22,034 | 4,126 | 2,088 | 42,087 |
| 10 < aₚ ≤ 50 | 3,003 | 9,226 | 1,982 | 1,091 | 15,302 |
| aₚ > 50 | 54 | 652 | 196 | 149 | 1,051 |
| All aₚ | 16,896 | 31,912 | 6,304 | 3,328 | 58,440 |

In Table 2, there is clear under-representation of geomagnetic storms in this vast dataset. This can cause limitations in model development, because over 98% of the dataset corresponds to aₚ≤50. Hierarchical modeling could be used for data of this nature, the examples of the present disclosure discuss the development of a single comprehensive model.

Methodology—Principal Component Analysis

Principal Component Analysis is an eigendecomposition technique that determines uncorrelated linear combinations of the data that maximize variance. PCA has been previously used to analyze atmospheric density models and accelerometer derived density sets. Researchers applied PCA to Challenging Minisatellite Payload (CHAMP) and Gravity Recovery and Climate Experiment (GRACE) accelerometer-derived density data in order to analyze the dominant modes of variance and identify phenomena encountered by the satellites. PCA has also been leveraged for dimensionality reduction to create linear dynamic reduced order models.

This dataset is a prime candidate for PCA with the goal of predictive modeling due to its high dimensionality. The three spatial dimensions are first flattened to make the dataset two-dimensional (time×space). Then a common logarithm of the density values is taken in order to reduce the variance of the dataset. Next, the temporal mean for each cell is subtracted to center the data and save it for later use. Finally, PCA is performed using the suds function in MATLAB to acquire the U, Σ, and V matrices (shown in Equation 2). PCA decomposes the data and separates spatial and temporal variations to uphold Equation 1.

x(s,t)=x̅(s)+\tilde{x}(s,t) and \tilde{x}(s,t)=Σᵢ₋₁^{r}αᵢ(t)Uᵢ(s) (1)

where x∈ [symbol] ⁿ is the model output state (HASDM density on full 3-D grid), x̅ is the mean, \tilde{x} is the variance, r is the choice of order truncation (here r=10), αᵢ are temporal coefficients, and Uᵢ are orthogonal modes, or basis functions. Equation 2 shows how to derive these modes.

$$X = [ \begin{matrix}\vert & \vert & \vert & & \vert \\ {\tilde{x}}_{1} & {\tilde{x}}_{2} & {\tilde{x}}_{3} & … & {\tilde{x}}_{m} \\ \vert & \vert & \vert & & \vert\end{matrix} ] and X = U Σ {V}^{T} \qquad ( 2 )$$

In Equation 2, m represents the ensemble size (two solar cycles with HASDM). X represents the normalized, centered data. The left unitary matrix, U, is made of orthogonal vectors that represent the modes of variation, and Σ is a diagonal matrix consisting of the squares of the eigenvalues that correspond to the vectors in U. The data (X) is encoded into temporal coefficients (αᵢ) by performing matrix multiplication between Σ and V^{T}). To decode from the coefficients to density, they are multiplied by U and the temporal mean is added at each cell.

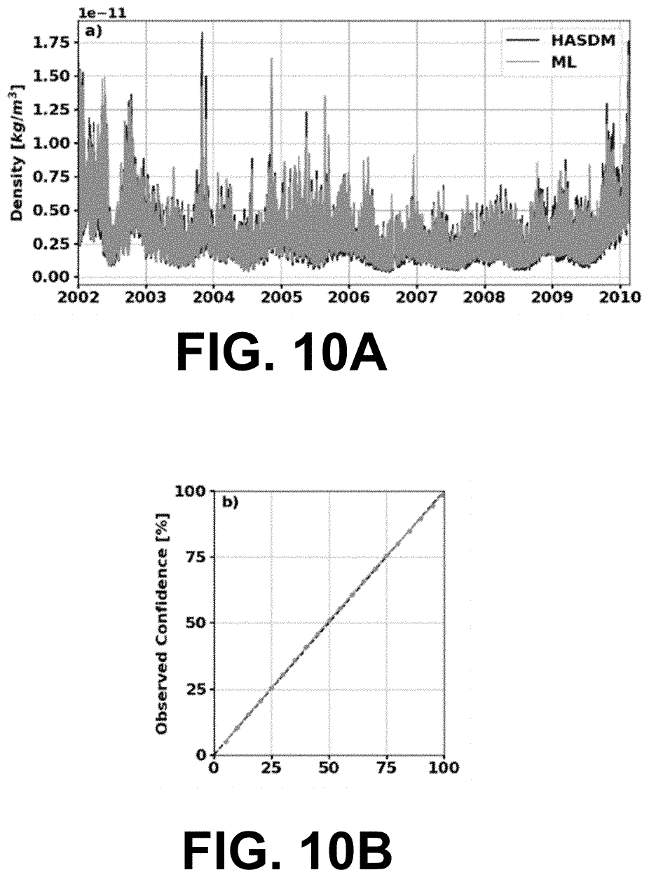

FIG. 8 shows the first ten PCA coefficients (αᵢ) generated for the HASDM database along with F₁₀ and aₚ using the methods described above.

Methodology—Hyperparameter Tuning

In machine learning, developing an accurate model previously required a manual architecture selection process does not guarantee optimal performance for a given application. Recent developments in hyperparameter tuning make this process much quicker and more thorough. According to various examples, KerasTuner is used, which allows the user to define the ranges and choices of any hyperparameter and choose a search algorithm. According to various embodiments, models were trained with one hundred trials (or architectures) with the first twenty-five being randomly sampled from the hyperparameter space while the last seventy-five trials take advantage of the tuner's Bayesian optimization scheme.

The tuner will train three identical models for each trial and return the lowest validation loss after one hundred training iterations, or epochs. The Bayesian optimization scheme chooses future architectures based on the validation losses resulting from previous trials. Once completed, the tuner returns the best ten models which can be evaluated on all three subsets of the data to find the most accurate and generalized model.

Methodology—Regression Modeling

A traditional approach to regression modeling with UQ is to develop Gaussian process (GP) models. In the early stages of model development, this approach was attempted by training GP regression models on each of the PCA coefficients. However, only ten years of data for could be used for training, limited by computational resources, which resulted in higher predictive error. In addition, the ten resulting models were 6.83 GB each making subsequent work cumbersome. Therefore, the results only pertain to the feedforward neural networks with MC dropout. There are three methods explored in the present disclosure for developing the best HASDM-ML model. First, a ROM using PCA for dimensionality reduction and a nonlinear ANN for prediction were created. This techniques was further modified by using a custom loss function in an attempt to obtain a model with calibrated uncertainty estimates. During experimentation, two loss functions were tested to achieve this: NLPD and CRPS.

ANNs have two key components: features (or inputs) and labels (or outputs). Three separate input sets were used for the regression models, the first two are explained in Table 3.

TABLE 3
List of inputs in the two sets used for model development

| JB2008 Inputs | | | Historical JB2008 Inputs | | |
|---|---|---|---|---|---|
| | Geo- | Tem- | | Geo- | Tem- |
| Solar | magnetic | poral | Solar | magnetic | poral |
| F₁₀, S₁₀, | aₚ, Dst | t₁, t₂ | F₁₀, S₁₀, | a_{pA}, aₚ, aₚ₃, | t₁, t₂ |
| M₁₀, Y₁₀, | | t₃, t₄ | M₁₀, Y₁₀, | aₚ₆, aₚ₉, aₚ₁₂₋₃₃, | t₃, t₄ |
| F_{81c}, S_{81c} | | | F_{81c}, S_{81c} | aₚ₃₆₋₅₇, Dst_{A}, Dst, | |
| M_{81c}, Y_{81c} | | | M_{81c}, Y_{81c} | Dst₃, Dst₆, Dst₉, | |
| | | | | Dst₁₂, Dst₁₅, Dst₁₈, Dst₂₁, | |

The first set is the JB2008 input set, referred to as JB. The SET HASDM density database contains evidence of post-storm cooling mechanisms which cannot be captured solely by geomagnetic indices at epoch. Therefore, a second set that is similar to the first but with a time history of the geomagnetic indices is introduced and referred to as as JBH (Historical JB2008). Unlike the actual JB2008 inputs, all of the input sets of the present disclosure contain sinusoidal transformations to the day of year (doy) and universal time (UT) inputs. The four resulting temporal inputs (shown in Equation 3) represent annual (t₁ and t₂) and diurnal (t₃ and t₄) variations.

$${t}_{1} = sin ( \frac{2 π d o y}{365.25} ) {t}_{2} cos ( \frac{2 π d o y}{365.25} ) \\ {t}_{3} = sin ( \frac{2 π U T}{24} ) {t}_{4} = cos ( \frac{2 π U T}{24} ) \qquad ( 3 )$$

The solar indices and proxies associated with inputs disclosed in Table 3 are further explained in Tobiska, W. K., B. R. Bowman, D. Bouwer, A. Cruz, K. Wahl, M. Pilinski, P. M. Mehta, and R. J. Licata (2021), The SET HASDM density database, Space Weather, p.e2020SW002682, doi:https://doi.org/10.1029/2020SW002682 and in Bowman, B., W. K. Tobiska, F. Marcos, C. Huang, C. Lin, and W. Burke (2008), A New Empirical Thermospheric Density Model JB2008 Using New Solar and Geomagnetic Indices, in AIAA/AAS Astrodynamics Specialist Conference, AIAA 2008-6438, both of which are included by reference herein in their entirety. The “81c” subscript refers to the 81-day centered average value. In the JB_{H} set, the geomagnetic indices are extensive in an effort to improve storm-time and post-storm modeling. The “A” subscript refers to the daily average, and the numerical subscripts refer to the value of the index that many hours prior to the epoch. The combination of two numbers references the number of previous hours the index is being averaged over. Upon analysis, it is determined that using different time histories of aₚ and Dst (shown in Table 3) resulted in more optimal performance. For completeness, the results will also be shown using an input set that adopts the same time history for Dst as the aₚ time history in Table 3. This input set will be referred to as JB_{H0}. As the geomagnetic inputs in the JB_{H} and JB_{H0} sets are in a time series format, the time-delay neural network (TDNN) approach was tested. TDNNs use convolutional layers to absorb the information of the time history of a given input and make the model time invariant. Tuners for the two historical input sets were run using the MSE loss function and there were no error reductions worthy of further investigation. Additionally, the architecture required for a TDNN adds significant complexity when implementing the NLPD and CRPS loss functions.

Methodology—Uncertainty Quantification

Dropout is a regularization tool often used in machine learning (ML) to prevent the model from overfitting to the training data. In standard feed-forward neural networks, each layer sends outputs from all nodes to those in the subsequent layer where they are introduced to weights and biases. Deep neural networks can have millions of parameters and thus are prone to overfitting. This causes undesired performance when interpolating or extrapolating.

Dropout layers use Bernoulli distributions, one for each node, with probability P. This makes the model probabilistic; each time a set of inputs are given to the model, the distributions are sampled. If a sample is “true”, the node's output is nullified, and the output of the layer is scaled based on the number of nullified outputs. Dropout is believed to make each node independently sufficient and not reliant on the outputs of other nodes in the layer.

In traditional use, dropout layers are only activated during training to uphold the deterministic nature of the model. However, measures can be taken in order for this feature to remain activated during prediction making the model probabilistic. When passing the same input set to the model a significant number of times (e.g., 1,000), there is a distribution of model outputs for each unique input. This process is referred to as Monte Carlo (MC) dropout. Essentially, every time the model is presented with a set of inputs, random nodes are dropped out providing a different functional representation of the model. It has been shown that MC dropout is a Bayesian approximation of a Gaussian process. According to various embodiments, the model of the present disclosure uses the input set to predict the ten (10) PCA coefficients. Through the bootstrapping method, the mean and variance for each of the coefficients are estimated. As the variance is different for each output/coefficient, this is a heteroskedastic problem. Each unique input can be passed to the model k times and there will be k×10 outputs. The mean and variance are computed from those outputs with respect to the repeated axis, k. The two loss functions used to improve uncertainty estimation (in addition to MSE) are NLPD and CRPS. NLPD is based on the logarithm of the probability density function (pdf) of the Gaussian distribution, and is shown in Equation 4.

$$NLPD ( y , μ , σ ) = \frac{{( y - μ )}^{2}}{2 {σ}^{2}} + \frac{log ( {σ}^{2} )}{2} + \frac{log ( 2 π )}{2} \qquad ( 4 )$$

In Equation 4, y is the ground truth, μ is the mean prediction, and σ is the predictive standard deviation, each being computed for all ten outputs making it heteroskedastic. The second loss function for uncertainty estimation is CRPS which is shown analytically in Equation 5. The main difference between NLPD and CRPS is that CRPS is based on the cumulative density function (cdf) of the Gaussian distribution as opposed to the pdf.

$$CRPS ( y , μ , σ ) = σ [ \frac{y - μ}{σ} erf ( \frac{y - μ}{\sqrt{2} σ} ) + \sqrt{\frac{2}{π}} exp ( - \frac{{( y - μ )}^{2}}{2 {σ}^{2}} ) - \frac{1}{\sqrt{π}} ] \qquad ( 5 )$$

As with Equation 4, μ and σ are computed using bootstrap methods, and this loss function is also heteroskedastic. An important aspect of using the loss functions described in Equations 4 and 5 is the preparation of the training data. The data is traditionally in the following form. The features are set up as the number of samples, n, and the number of inputs, n₁ making the shape—(n×n₁). The labels are set up as the number of samples and the number of outputs, nₒ making the shape—(n×nₒ). To implement these loss functions, each input and output are stacked by the number of MC samples, k. This is a repeated axis, meaning all samples in this axis are identical. The resulting shapes of the features and labels are (n×k×n₁) and (n×k×nₒ), respectively. This allows for the determination of the mean and standard deviation for each unique input within the loss function.

Methodology—Latent Space UQ

Since there are multiple models and loss functions to compare, a metric to judge each model's ability to provide reliable uncertainty estimates is implemented. To do so, the calibration error equation of Equation 6 is applied

$$Calibration Error = {\sum }_{i = 1}^{r} {\sum }_{i = j}^{m} \vert p ( {z}_{i , j} ) - p ( {\hat{z}}_{i , j} ) \vert \qquad ( 6 )$$

In Equation 6, m is the number of confidence intervals investigated, r is the choice order of truncation for PCA (the number of model outputs), p(z) is the expected confidence, and p(\hat{z}) is the observed confidence. The confidence intervals of interest in this work span from 5% to 95% with 5% increments appended with 99%. p(\hat{z}) is computed empirically, shown in Equation 7.

$$p ( \hat{z} ) = \frac{1}{n} {\sum }_{i = 1}^{n} ΙΙ ( {\hat{z}}_{i}^{l} < {z}_{i} < {\hat{z}}_{i}^{u} ) \qquad ( 7 )$$

where n is the number of samples, [symbol] is the indicator function, \hat{z}ᵢ^{l}, is the lower bound of the confidence interval, \hat{z}ᵢ^{u} the upper bound of the confidence interval, and zᵢ is the sample. Equation 8 is used to compute the bounds.

\hat{z}ᵢ^{l}=μ−zσ and \hat{z}ᵢ^{u}=μ+zσ (8)

where z is the critical value used for the confidence interval. This is calculated using Equation 9.

z=\sqrt{2}erf⁻¹(CL) (9)

In Equation 9, CL is the confidence level of interest (e.g. 95% or 0.95).

Methodology—Density UQ

While latent space calibration is important because the model is trained on the PCA coefficients, determining the reliability of the model's predictions on the resulting density is the ultimate goal. To examine this, the orbits of CHAMP and GRACE are analyzed. These satellites had onboard accelerometers from which mass density has been estimated. The model is evaluated 1,000 times every three hours across the entire availability of CHAMP and GRACE measurements and are interpolated to the satellite locations. This allows the observed confidence of the HASDM-ML model to be computed relative to the HASDM database. Due to the redundancy and computational expense, only the model and database density are interpolated every 500 samples (5,000 and 2,500 seconds for CHAMP and GRACE-A, respectively). This provides a wide view of the model's UQ capabilities. The CHAMP comparison uses 23,795 model prediction epochs (40.7% of the total available data) with the density being interpolated to at least two satellite positions per prediction due to the cadence of this study. The GRACE comparison uses 24,602 model prediction epochs (42.1% of the total available data) with the density being interpolated to at least four satellite positions per prediction.

Geomagnetic storms are particularly difficult conditions to model accurately. Therefore, four (4) geomagnetic storms from 2002-2004 are reviewed to evaluate HASDM309 ML's reliability across unique events. Two of the events take place in 2002, which is outside the training dataset, while the other two are from 2003 and 2004 and are seen in training. To conduct this assessment, the methodology from the storm time case study of Licata, R. J., W. K. Tobiska, and P. M. Mehta (2020b), Benchmarking Forecasting Models for Space Weather Drivers, Space Weather, 18(10), e2020SW002,496, doi:https://doi.org/10.1029/2020SW002496, which is incorporated by reference herein in its entirety, is applied. The model is evaluated over a six (6) day period encompassing a storm then interpolated to the CHAMP locations (10 second cadence). During each three-hour prediction period, the density grids remains constant. All 1,000 HASDM-ML density variations are then averaged across each orbit using the mean altitude to determine the orbital period. The mean and 95% confidence bounds are computed to compare to the corresponding HASDM densities and shown in the figure in an orbit-averaged form. In total, the six days amounts to forty-eight model prediction epochs which results in 51,840 interpolated densities (1,000 MC runs) from which the observed confidence values are computed.

Results

Upon running each input set with all three loss functions through individual tuners, the best ten models from each tuner are evaluated on the entire train, validation and test sets 1,000 times. The mean absolute error for each subset is computed based on the mean prediction transformed back to the density space. The calibration error score (Equation 6) is computed using the mean and standard deviation from the 1,000 runs in the latent space. The mean absolute error results from the best of the ten models for each input set/loss function are shown in Table 4.

TABLE 4
Mean Absolute for the best model from each technique across training,
validation, and test data

| | Training | | | Validation | | | Test | | |
|---|---|---|---|---|---|---|---|---|---|
| Technique | JB | JB_{H} | JB_{H0} | JB | JB_{H} | JB_{H0} | JB | JB_{H} | JB_{H0} |
| MSE | 10.38% | 8.73% | 8.47% | 12.00% | 10.48% | 9.91% | 11.95% | 10.71% | 10.51% |
| NLPD | 10.07% | 9.07% | 8.81% | 11.93% | 10.69% | 9.87% | 11.41% | 10.69% | 10.05% |
| CRPS | 9.67% | 8.64% | 8.26% | 11.56% | 10.55% | 9.69% | 11.76% | 10.43% | 10.69% |

The addition of historical geomagnetic indices clearly improves the model performance with error reductions upwards of 2%. As previously mentioned, the motivation for using the time series geomagnetic indices was to improve storm-time and post-storm performance.

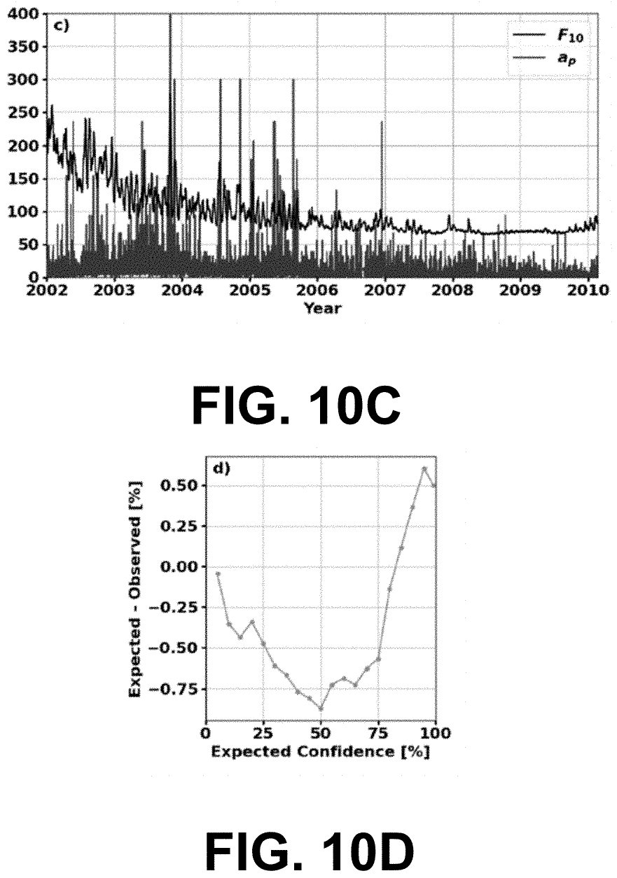

However, Table 2 shows that these conditions account for a small subset of the data meaning the notable performance improvement with the JB_{H} and JB_{H0} input sets show that it likely improves the predictions across all conditions. In general, the CRPS models have the lowest error, and the JB_{H0} models have the lowest error in terms of the input sets. Table 5 shows the calibration error score for the same models. The incorporation of the custom loss functions reduce the calibration error score by an order of magnitude relative to models trained with MSE, which tend to underestimate the uncertainty. The best performing loss function, in regards to calibration, is NLPD. To choose the best overall model, the test performance is focused on as that data is completely independent from the training process. Furthermore, the most calibrated model is valued as reliable uncertainty estimates are the most valuable asset for a thermospheric density model. The JB_{H} and NLPD model is within 1% of the error of all better-performing models, and it has the lowest test calibration error score with satisfactory values for the training and validation data. As the calibration error score is a composite of the scores from each coefficient, the calibration curves of all coefficients on the independent test set for the best JB_{H}+NLPD model are shown, in panel (b), alongside the best JB_{H}+MSE model, in panel (a), for comparison in FIG. 9. In particular, FIG. 9 illustrates the expected vs. observed confidence of all 10 PCA coefficients for HASML-ML on the test set in accordance to various embodiments of the present disclosure.

TABLE 5
Calibration error score for the best model from each technique across training,
validation, and test data.

| | Training | | | Validation | | | Test | | |
|---|---|---|---|---|---|---|---|---|---|
| Technique | JB | JB_{H} | JB_{H0} | JB | JB_{H} | JB_{H0} | JB | JB_{H} | JB_{H0} |
| MSE | 3.871 | 3.744 | 3.758 | 3.962 | 3.898 | 3.901 | 4.004 | 3.979 | 3.972 |
| NLPD | 0.3404 | 0.3061 | 0.2794 | 0.3084 | 0.2506 | 0.2836 | 0.2212 | 0.1757 | 0.2790 |
| CRPS | 0.3292 | 0.7933 | 0.4464 | 0.2270 | 0.4634 | 0.2735 | 0.2399 | 0.2387 | 0.2950 |

The calibration curve in panel (b) of FIG. 9 for all PCA coefficients roughly follows the perfectly calibrated 45° line with a₅ being the only coefficient that prominently underestimates uncertainty. However, there is minimal contribution to the full-state (density) after the first few coefficients, so this should not greatly impact the resulting density. In sharp contrast, panel (a) of FIG. 9 shows the model trained with the MSE loss function is not nearly calibrated, as is evident in Table 5. There is a strong underestimation of the uncertainty at all confidence levels, because the model is not trained with any terms for its variance.

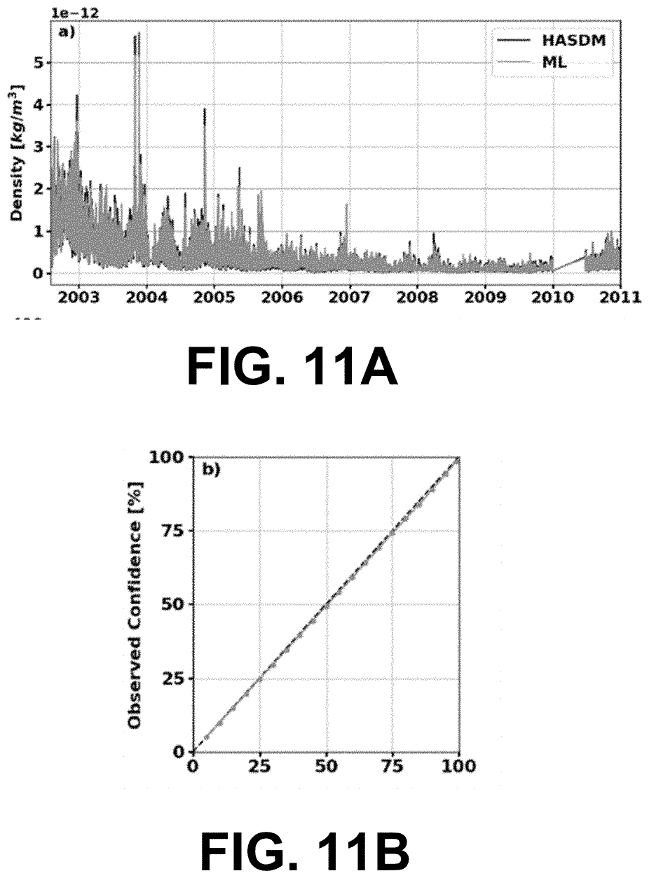

The JB_{H}+NLPD model shown in FIG. 9 will be the focus of all subsequent analyses and will be referred to as HASDM-ML. To investigate the model's reliability on density in an operational nature, the orbits of CHAMP and GRACE-A are observed each over eight year periods with a cumulative altitude range of 300-530 km. HASDM-ML was evaluated in three-hour increments from 2002-2011, and was interpolated to the satellite positions. The results for the CHAMP orbit are displayed in FIGS. 10A-D. In particular, FIG. 10A shows the HASDM and mean HASDM-ML density interpolated to CHAMP positions, FIG. 10B shows the expected vs observed calibration curve, FIG. 10C shows F₁₀ and aₚ for the period corresponding to FIG. 10A, and FIG. 10D shows the difference between expected and observed confidence corresponding to FIG. 10B. Discontinuities in FIG. 10A and FIG. 10C represent data gaps.

In particular, FIG. 10A shows a clear similarity in the HASDM and HASDM-ML mean densities. The ML model's density formulation does not appear to contain any major discrepancies. The surrogate ML model is imperfect in its mean prediction, as seen in Table 4, but FIGS. 10B and 10D show that the density uncertainty is reliable. The calibration curve is exceptional with the observed confidence being within 1% of the expected confidence for all 20 confidence levels tested.

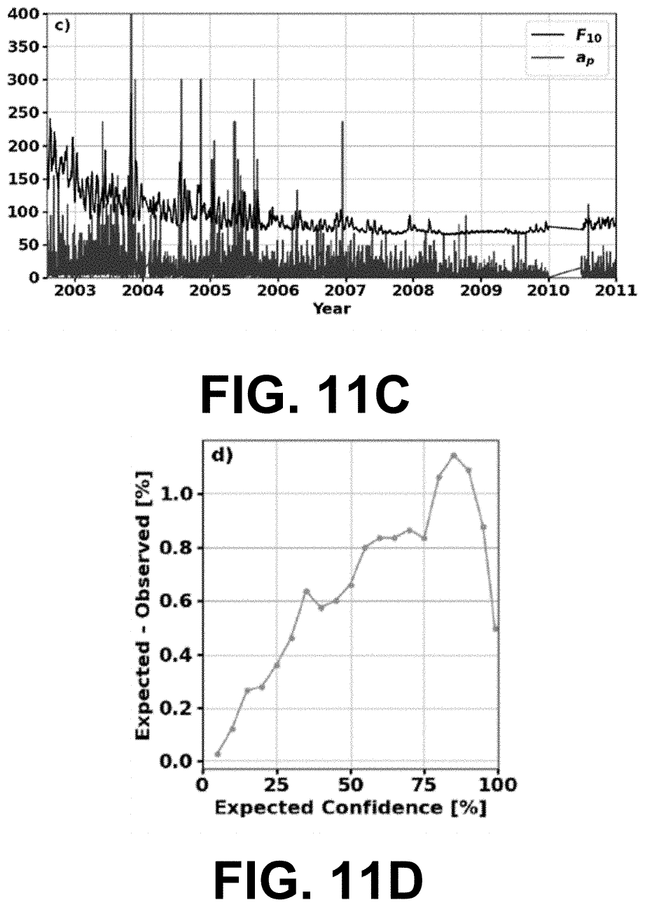

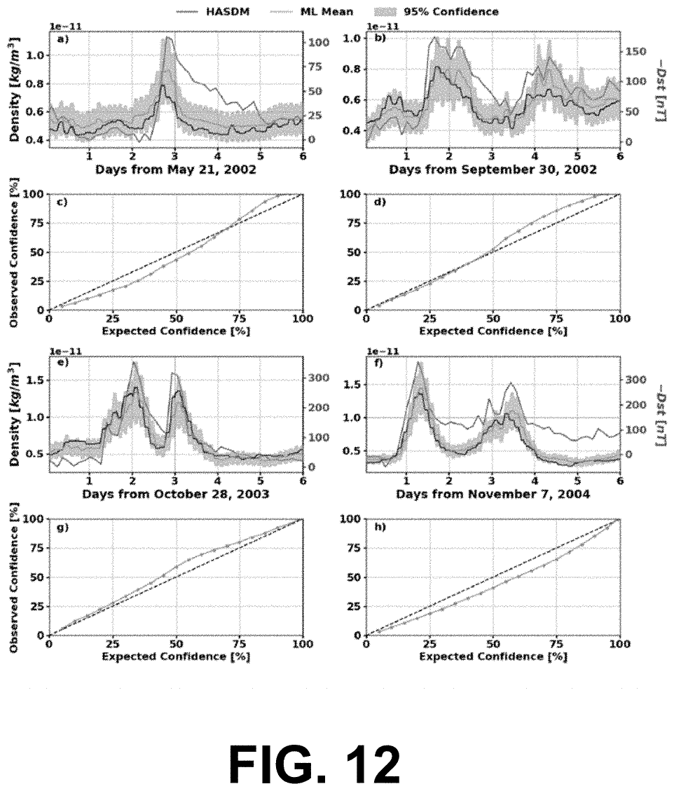

FIGS. 11A-11D show the same analysis along the GRACE-A orbit. Again, FIG. 11A shows that HASDM and HASDM-ML mean densities are quite similar. FIGS. 11B and 11D also demonstrate that although the densities are not identical, HASDM-ML provides uncertainty estimates that are reliable. FIG. 11D reveals that at the higher GRACE altitudes, there is slightly less agreement with the expected and observed confidences with the largest discrepancy being just over 1%. To perform the simulations displayed in FIGS. 10A-D and FIGS. 11A-D, the model had to be evaluated 23,795,000 and 24,602,000 times for CHAMP and GRACE, respectively. These numbers come from the number of HASDM prediction epochs previously discussed and the number of MC runs (1,000). HASDM-ML can perform these predictions in 17.27 seconds for CHAMP and 17.54 seconds for GRACE on a laptop with a NVIDIA GeForce GTX 1070 Mobile graphics card. Using CPU, the model takes 143 seconds for CHAMP and 152 seconds for GRACE. FIG. 12 shows HASDM and HASDM-ML orbit-averaged densities during four geomagnetic storms with confidence bounds and the associated calibration curves.

Across all of the storms investigated, the mean prediction of HASDM-ML follows the trend of HASDM density. Even when the model deviates, HASDM densities are mostly captured by the uncertainty bounds. Panels (a) and (b) of FIG. 12 represent storms not contained in the training dataset which show that HASDM-ML is well-generalized, even during these highly nonlinear events. The calibration curves corresponding to each event show the robust nature of HASDM-ML's uncertainty estimates. While the observed confidence values deviated from the expected values, these are highly nonlinear periods where density models tend to be unreliable.

Results—HASDM-ML Performance Metrics

To assess the conditions in which HASDM-ML can improve, the global mean absolute errors are computed as a function of space weather conditions. The results are shown in Table 6 and the number of samples in each bin can be found in Table 2.

The results from Table 6 show that HASDM-ML is robust to different F₁₀ and aₚ ranges when aₚ≤50. The only conditions in which the mean absolute error exceeds 11% is when aₚ>50, which only accounts for 1.80% of the samples. This shows that more samples are required for this specific condition in both the training and evaluation phases. The last row contains the errors only as a function of F₁₀ which shows that across all four conditions, the error deviates by only 1.24%. The bottom-right cell shows that the error across all 20 years of available data is only 9.71%.

TABLE 6
Mean absolute error across global grid for HASDM-ML as
a function of space weather conditions

| | | 75 < F₁₀ ≤ | 150 < F₁₀ ≤ | | |
|---|---|---|---|---|---|
| | F₁₀ ≤ 75 | 150 | 190 | F₁₀ > 190 | All F₁₀ |
| aₚ ≤ 10 | 8.96% | 9.78% | 9.97% | 9.14% | 9.50% |
| 10 < aₚ ≤ 50 | 9.76% | 10.05% | 10.87% | 9.90% | 10.09% |
| aₚ > 50 | 15.35% | 12.86% | 13.23% | 12.55% | 13.01% |
| All aₚ | 9.12% | 9.92% | 10.36% | 9.55% | 9.71% |

### SUMMARY

According to various embodiments, a surrogate ML model for the SET HASDM density database with robust and reliable uncertainty estimation capabilities is disclosed. Principal component analysis was selected for dimensionality reduction due to its versatile nature. A Bayesian search algorithm was leveraged to identify an optimal architecture for each input set and loss function tested. Of the nine input-loss function combinations explored, the combination of a JB2008 input set with historical geomagnetic drivers and the heteroskedastic NLPD loss function resulted in the most comprehensive model. This model, HASDM-ML, has 9.07% error across the twelve year training set and an average 10.69% error over the combined eight year validation/test sets. It also had the lowest calibration error score on the test set, meaning it was the most calibrated to independent data. The calibration curves for each output across the entire twenty year dataset to that of the MSE model were compared with the same inputs. This showed that the MSE model considerably underestimated the uncertainty while the NLPD model was well-calibrated across the ten outputs.

Upon selecting HASDM-ML, the uncertainty capabilities across the entire orbits of CHAMP and GRACE-A were evaluated, both using almost half of the time span of the dataset. This assessment showed that the mean prediction at the satellite locations closely matched that of the HASDM dataset. Across all twenty confidence intervals tested over this period, the model provided an observed confidence that never deviated more than 1% of the expected confidence for CHAMP's orbit and never deviated more than 1.15% for GRACE-A's orbit.

A separate storm-time evaluation unveiled that across four storms, HASDM-ML provides similar density to HASDM and its uncertainty estimates remained robust and reliable. The results from the density calibration tests are significant, because no thermospheric density model to date provides uncertainty estimates. Additionally, uncertainty estimates themselves are not meaningful unless they are well-calibrated, and HASDM-ML is able to provide that.

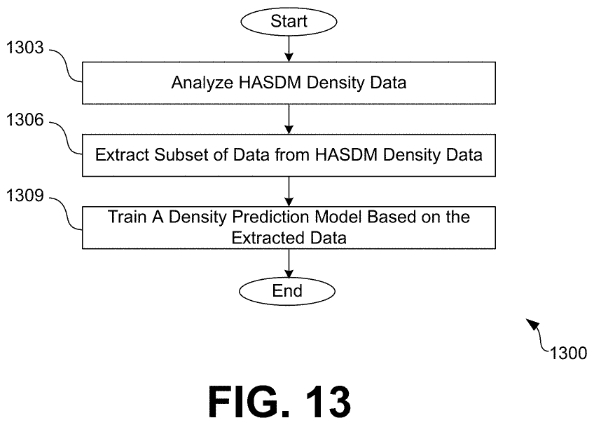

Referring next to FIG. 13, shown is a flowchart 1300 that includes an example of the operations of a portion of the space density prediction system 100 according to various embodiments. It is understood that the flowchart of FIG. 13 provides merely an example of the many different types of functional arrangements that may be employed to implement the operations of the portion of the space density prediction system 100 as described herein. As an alternative, the flowchart of FIG. 13 may be viewed as depicting an example of elements of a method implemented in a computing environment according to one or more embodiments.

Beginning with box 1303, the space density predicting system 100 analyzes the HASDM. As previously discussed, HASDM is used operationally by JSpOC to make predictions of three-day maneuvers. Every three hours, HASDM uses a thermospheric density mod& and continuously derives densities from several dozen calibration satellites to achieve <5% density uncertainty. HASDM describes density as a function of latitude, local solar tin e and altitude. A time-series filter then predicts the density correction parameters as a function of predicted solar radio flux index F_{10.7} and predicted geomagnetic storm index up to three days into the future. The estimated and predicted density fields are then used to first differentially correct all the drag influenced orbits (over 6000) in the NORAD catalog. Then, they are used to predict all satellite trajectories three days out.

At box 1306, the space density prediction system 100 extracts at least a first subset of input data from the HASDM dataset and at least a first subset of output data from the HASDM dataset. According to various embodiments of the present disclosure, Principal Component Analysis (PCA) for dimensionality reduction and artificial neural networks for modeling the reduced state with input drivers is applied. PCA decomposes the spatial variations into mutually orthogonal, time-independent coherent structures or basis functions (BFs; also known as principal components—PCs or empirical orthogonal functions—EOFs) that capture the covariance in space.

For examples, the three spatial dimensions are first flattened to make the dataset two-dimensional (time×space). Then a common logarithm of the density values is taken in order to reduce the variance of the dataset. Next, the temporal mean for each cell is subtracted to center the data and save it for later use. Finally, PCA is performed using the suds function in MATLAB to acquire the U, Σ, and V matrices (shown in Equation 2). PCA decomposes the data and separates spatial and temporal variations to uphold Equation 1.

At block 1309, the space density prediction system 100 trains the density prediction model based at least in part on the extracted data. According to various embodiments, the density prediction model can be generated based at least in part on one or more machine learning algorithms as applied to one or more training sets and/or reference data sets associated with the HASDM. In various examples, a ROM using PCA for dimensionality reduction and a nonlinear ANN for prediction is created. This technique was further modified by using a custom loss function in an attempt to obtain a model with calibrated uncertainty estimates. According to various examples, the trained density prediction model can be verified for performance.

As can be appreciated, the density prediction model is trained with the primary output being mass density on the three-dimensional grid (e.g., latitude, longitude, altitude). In some embodiments, the output number density and temperature may be included on the 3-D grid. According to various embodiments, the mass density output can be analyzed for space traffic management. For example, in various embodiments, the space density prediction system 100 can analyze the density output for a given satellite based at least in part on satellite data (size, location, material, etc.) and/or other atmospheric characteristics associated with the given satellite to determine a likelihood of collision for the given satellite with another object. Based on the likelihood of collision, the given satellite can be moved. For example, if the likelihood of collision is below a given threshold, the given satellite may remain in the same location. However, if the likelihood of collision meets or exceeds a given threshold, the given satellite may be moved to avoid the potential collision. After the density prediction model is trained and verified, this portion of the process proceeds to completion.

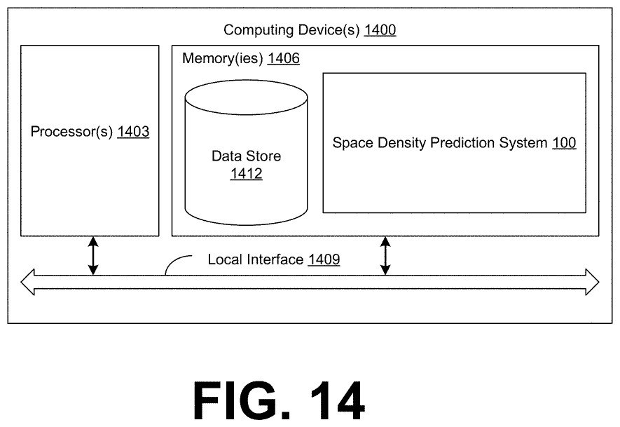

With reference now to FIG. 14, shown is one example of at least one computing device 1400 (e.g., an interfacing device, central server, server, or other network device) that performs various functions of the space density prediction system 100 in accordance with various embodiments of the present disclosure. Each computing device 1400 includes at least one processor circuit, for example, having a processor 1403 and a memory 1406, both of which are coupled to a local interface. To this end, each computing device 1400 may be implemented using one or more circuits, one or more microprocessors, microcontrollers, application specific integrated circuits, dedicated hardware, digital signal processors, microcomputers, central processing units, field programmable gate arrays, programmable logic devices, state machines, or any combination thereof. The local interface 1409 may comprise, for example, a data bus with an accompanying address/control bus or other bus structure as can be appreciated. Each computing device 1400 can include a display for rendering of generated graphics such as, e.g., a user interface and an input interface such, e.g., a keypad or touch screen to allow for user input. In addition, each computing device 1400 can include communication interfaces (not shown) that allows each computing device 1400 to communicatively couple with other communication devices. The communication interfaces may include one or more wireless connection(s) such as, e.g., Bluetooth or other radio frequency (RF) connection and/or one or more wired connection(s).

Stored in the memory 1406 are both data and several components that are executable by the processor 1403. In particular, stored in the memory 1406 and executable by the processor 1403 is the space density prediction system 100, and/or other applications. Also stored in the memory 1406 may be a data store 1412 and other data. It is understood that there may be other applications that are stored in the memory 1406 and are executable by the processor 1403 as can be appreciated. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Delphi®, Flash®, LabVIEW®, MATLAB® or other programming languages.

A number of software components are stored in the memory 1406 and are executable by the processor 1403. In this respect, the term “executable” means a program file that is in a form that can ultimately be run by the processor 1403. Examples of executable programs may be, for example, a compiled program that can be translated into machine code in a format that can be loaded into a random access portion of the memory 1406 and run by the processor 1403, source code that may be expressed in proper format such as object code that is capable of being loaded into a random access portion of the memory 1406 and executed by the processor 1403, or source code that may be interpreted by another executable program to generate instructions in a random access portion of the memory 1406 to be executed by the processor 1403, etc. An executable program may be stored in any portion or component of the memory 1406 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 1406 is defined herein as including both volatile and nonvolatile memory and data storage components. Volatile components are those that do not retain data values upon loss of power. Nonvolatile components are those that retain data upon a loss of power. Thus, the memory 1406 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 1403 may represent multiple processors and the memory 1406 may represent multiple memories that operate in parallel processing circuits, respectively. In such a case, the local interface 1409 may be an appropriate network that facilitates communication between any two of the multiple processors, between any processor and any of the memories, or between any two of the memories, etc. The local interface 1409 may comprise additional systems designed to coordinate this communication, including, for example, performing load balancing. The processor may be of electrical or of some other available construction.

Although the space density prediction system 100, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, or other components, etc. Such technologies are generally well known by those skilled in the art and, consequently, are not described in detail herein.

Also, any logic or application described herein, including the space density prediction system and/or application that comprises software or code can be embodied in any non-transitory computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system. The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random-access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A system, comprising:
at least one computing device;
at least one application executable in the at least one computing device, wherein, when executed, the at least one application causes the at least one computing device to at least:
analyze High Accuracy Satellite Drag Model (HASDM) data associated with a HASDM model, the HASDM data corresponding to two solar cycles;
extract at least one subset of input data and at least one subset of output data from the HASDM data; and
train a density prediction model using machine learning and based at least in part on the at least one subset of input data and the at least one subset of output data, the density prediction model being trained to output a mass density map for accurately predicting trajectories of satellites.

2. The system of claim 1, wherein the input data comprises at least one of one or more solar indices, one or more geomagnetic indices, a day of the year, a latitude, a longitude, or a time of the day.

3. The system of claim 1, wherein the output data comprises mass density on a three-dimensional grid.

4. The system of claim 1, wherein the output data further comprises at least one of temperature or a number density.

5. The system of claim 1, wherein, when executed, the at least one application causes the at least one computing device to reduce dimensionality of the HASDM data based at least in part on an application of principal component analysis (PCA).

6. The system of claim 1, wherein performance of the density prediction model is improved based at least in part on an application of a negative logarithm of predictive density (NLPD) loss function.

7. The system of claim 1, wherein training the density prediction model is based at least in part on nonlinear reduced order modeling, and the at least one subset of input data and the at least one subset of output data correspond to reduced data.

8. The system of claim 1, wherein training the model comprises applying different combinations of inputs extracted from the HASDM data.

9. The system of claim 1, wherein, when executed, the at least one application further causes the at least one computing device to at least determine a likelihood of collision associated with a given object based at least in part on the mass density map and object data.

10. The system of claim 9, wherein the given object comprises a satellite, and the object data comprises a location of the satellite.

11. The system of claim 9, wherein, when executed, the at least one application further causes the at least one computing device to at least determine a trajectory for the given object based at least in part on the mass density map and the likelihood of collision in order to avoid a collision.

12. A method, comprising:
analyzing, via at least one computing device, High Accuracy Satellite Drag Model (HASDM) data associated with a HASDM model, the HASDM data corresponding to two solar cycles;
extracting, via the at least one computing device, at least one subset of input data and at least one subset of output data from the HASDM data; and
training, via the at least one computing device, a density prediction model using machine learning and based at least in part on the at least one subset of input data and the at least one subset of output data, the density prediction model being trained to output a mass density map for accurately predicting trajectories of satellites.

13. The method of claim 12, wherein the input data comprises at least one of one or more solar indices, one or more geomagnetic indices, a day of the year, a latitude, a longitude, a time of the day,

14. The method of claim 12, wherein the output data comprises mass density on a three-dimensional grid.

15. The method of claim 12, wherein the output data further comprises at least one of temperature or a number density.

16. The method of claim 12, further comprising reducing, via the at least one computing device, dimensionality of the HASDM data based at least in part on an application of at least one of principal component analysis (PCA)

17. The method of claim 12, wherein training the density prediction model is based at least in part on reduced order modeling, and the at least one subset of input data and the at least one subset of output data correspond to reduced data.

18. The method of claim 10, further comprising determining, via the at least one computing device, a likelihood of collision associated with a given object based at least in part on the mass density map and object data.

19. The method of claim 18, wherein the given object comprises a satellite or debris object, and the object data comprises a location of the satellite or the debris object.

20. The method of claim 18, further comprising determining a trajectory for the given object based at least in part on the mass density map and the likelihood of collision in order to avoid a collision.
